(19) United States
(12) Patent Application Publication
(10) Pub. No.: US 2025/0098389 A1
(43) Pub. Date: Mar. 20, 2025

(54) SUBSTRATE AND LIGHT EMITTING DEVICE

(71) Applicant: NICHIA CORPORATION, Anan-shi (JP)

(72) Inventors: Norifumi SASAOKA, Tokushima-shi (JP); Shoichi YAMADA, Anan-shi (JP); Kunihiro IZUNO, Anan-shi (JP); Daisuke IWAKURA, Komatsushima-shi (JP); Yoshiyuki KAGEYAMA, Tokushima-shi (JP); Hiroaki KURODA, Anan-shi (JP)

(73) Assignee: NICHIA CORPORATION, Anan-shi (JP)

(21) Appl. No.: 18/883,216

(22) Filed: Sep. 12, 2024

(30) Foreign Application Priority Data
Sep. 20, 2023 (JP) 2023-153916

(51) Int. Cl. H01L 33/64; H01L 25/075

(52) U.S. Cl. CPC H10H 20/8581; H01L 25/0753

(57) ABSTRACT

A substrate includes a first member having a through hole extending from an upper surface to a lower surface thereof, and a second member disposed inside the through hole. The second member includes a first region containing graphite, a second region located outward of the first region in a top view, containing graphite and a thermally conductive material that contains at least one of a metal or a ceramic, and having a volume fraction of the graphite lower than a volume fraction of the graphite in the first region, and a third region located outward of the second region in the top view, containing a thermally conductive material that contains at least one of a metal or a ceramic, and having a volume fraction of the thermally conductive material higher than a volume fraction of the thermally conductive material in the second region.

### CROSS-REFERENCE TO RELATED APPLICATIONS

This application is based on and claims priority to Japanese Patent Application No. 2023-153916, filed on Sep. 20, 2023, the entire contents of which are incorporated herein by reference.

### TECHNICAL FIELD

The present disclosure relates to a substrate and a light emitting device.

### BACKGROUND

In light emitting devices, improvement of heat dissipation is desired from the viewpoint of increasing the luminance of light emitting elements. PCT Patent Publication No. WO2019/116946 describes a clad material that is suitably used as the material of a heat dissipation plate for an electronic-component-mounted substrate. The clad material is obtained by laminating Mo—Cu layers on both surfaces of a Cu-graphite layer via metal films, and the Cu-graphite layer is made of a sintered body of graphite powder having a Cu film on the surface thereof.

### SUMMARY

The present disclosure provides a substrate and a light emitting device having good heat dissipation.

A substrate according to one embodiment of the present disclosure include a first member having a through hole extending from an upper surface to a lower surface thereof, and a second member disposed inside the through hole. The second member includes a first region containing graphite, a second region located outward of the first region in a top view, containing graphite and a thermally conductive material that contains at least one of a metal or a ceramic, and having a volume fraction of the graphite lower than a volume fraction of the graphite in the first region, and a third region located outward of the second region in the top view, containing a thermally conductive material that contains at least one of a metal or a ceramic, and having a volume fraction of the thermally conductive material higher than a volume fraction of the thermally conductive material in the second region.

A light emitting device according to one embodiment of the present disclosure includes a substrate, and a light source disposed above the substrate. The substrate includes a first member having a through hole extending from an upper surface to a lower surface thereof, and a second member disposed inside the through hole. The second member includes a first region including graphite and located at a position overlapping the light source in a top view, a second region located outward of the first region in the top view, including graphite and a thermally conductive material that contains at least one of a metal or a ceramic, and having a volume fraction of the graphite lower than a volume fraction of the graphite in the first region, and a third region located outward of the second region in the top view, including a thermally conductive material that contains at least one of a metal or a ceramic, and having a volume fraction of the thermally conductive material higher than a volume fraction of the thermally conductive material in the second region.

### BRIEF DESCRIPTION OF THE DRAWINGS

Other objects and further features of the present invention will be apparent from the following detailed description when read in conjunction with the accompanying drawings, in which:

FIG. 1 is a schematic top view illustrating an example of a light emitting device according to a first embodiment;

FIG. 2 is a schematic cross-sectional view of the light emitting device according to the first embodiment, taken through line II-II of FIG. 1;

FIG. 3 is a schematic cross-sectional view of a light emitting device according to a first modification of the first embodiment;

FIG. 4 is a schematic cross-sectional view of a light emitting device according to a second embodiment;

FIG. 5 is a schematic cross-sectional view of a light emitting device according to a first modification of the second embodiment;

FIG. 6A is a schematic cross-sectional view of a light emitting device according to a second modification of the second embodiment;

FIG. 6B is a partially enlarged view of a region VIB illustrated in FIG. 6A;

FIG. 7 is a schematic cross-sectional view of a light emitting device according to a third modification of the second embodiment;

FIG. 8A is a schematic cross-sectional view illustrating a method of manufacturing a substrate according to an embodiment;

FIG. 8B is a schematic cross-sectional view illustrating the method of manufacturing the substrate according to the embodiment;

FIG. 8C is a schematic cross-sectional view illustrating the method of manufacturing the substrate according to the embodiment;

FIG. 8D is a schematic cross-sectional view illustrating the method of manufacturing the substrate according to the embodiment;

FIG. 9A is a schematic cross-sectional view illustrating a method of producing a second member of the substrate according to the embodiment;

FIG. 9B is a schematic cross-sectional view illustrating the method of producing the second member of the substrate according to the embodiment;

FIG. 9C is a schematic cross-sectional view illustrating the method of producing the second member of the substrate according to the embodiment;

FIG. 9D is a schematic cross-sectional view illustrating the method of producing the second member of the substrate according to the embodiment;

FIG. 9E is a schematic cross-sectional view illustrating the method of producing the second member of the substrate according to the embodiment;

FIG. 10A is a schematic cross-sectional view illustrating a method of manufacturing a light emitting device according to the embodiment; and

FIG. 10B is a schematic cross-sectional view illustrating the method of manufacturing the light emitting device according to the embodiment.

### DETAILED DESCRIPTION

Light emitting devices according to embodiments of the present disclosure will be described in detail below with reference to the accompanying drawings. The embodiments described below are examples of light emitting devices that embody the technical ideas of the present disclosure, but the present disclosure is not limited to the described embodiments. In addition, unless otherwise specified, the dimensions, materials, shapes, relative arrangements, and the like of components described in the embodiments are not intended to limit the scope of the present disclosure thereto, but are described as examples. The sizes, positional relationships, and the like of members illustrated in the drawings may be exaggerated for clearer illustration. Further, in the following description, the same names and reference numerals denote the same or similar members, and a repeated detailed description thereof will be omitted as appropriate. An end view illustrating only a cut surface may be used as a cross-sectional view.

In the drawings, directions may be indicated by an X-axis, a Y-axis, and a Z-axis, which are orthogonal to one another. A direction indicated by an arrow in the X-axis direction is referred to as a +X direction, and a direction opposite to the +X direction is referred to as a −X direction. A direction indicated by an arrow in the Y-axis direction is referred to as a +Y direction, and a direction opposite to the +Y direction is referred to as a −Y direction. A direction indicated by an arrow in the Z-axis direction is referred to as a +Z direction, and a direction opposite to the +Z direction is referred to as a −Z direction. Further, the term “top view” as used in the embodiments refers to viewing an object from the +Z direction. However, these directions do not limit the orientation of a light emitting device during use, and the orientation of the light emitting device is arbitrary. In addition, in the embodiments, a surface of an object when viewed from the +Z direction is referred to as an “upper surface,” and a surface of the object when viewed from the −Z direction is referred to as a “lower surface.” In the embodiments described below, each of the phrases “along the X-axis,” “along the Y-axis,” and “along the Z-axis” includes a case where the object has an inclination in a range of +10° with respect to the corresponding one of the axes. Further, in the embodiments, the term “orthogonal” may include an error within +10° with respect to 90°.

In the present disclosure, polygonal shapes, such as triangular shapes and quadrangular shapes, including polygonal shapes with rounded corners, beveled corners, angled corners, reverse-rounded corners are also referred to as polygonal shapes. Further, not only shapes with such modification at corners (end of sides) but also shapes with modifications at intermediate portions of sides of the shapes are also referred to as polygonal shapes. That is, shapes that are based on polygonal shapes and partially modified are also interpreted as “polygonal shapes” in the present disclosure.

The same applies not only to polygonal shapes but also to terms representing specific shapes such as trapezoidal shapes, circular shapes, projections, and recesses. The same also applies when referring to sides forming such a shape. That is, even when a corner or an intermediate portion of a certain side is modified, the “side” is construed as including the modified portion. When a “polygonal shape or a “side” without partial modification is to be distinguished from a modified shape, “strict” will be added to the description as in, for example, a “strict quadrangular shape.”

### FIRST EMBODIMENT

### Example of Overall Configuration of Light Emitting Device 1

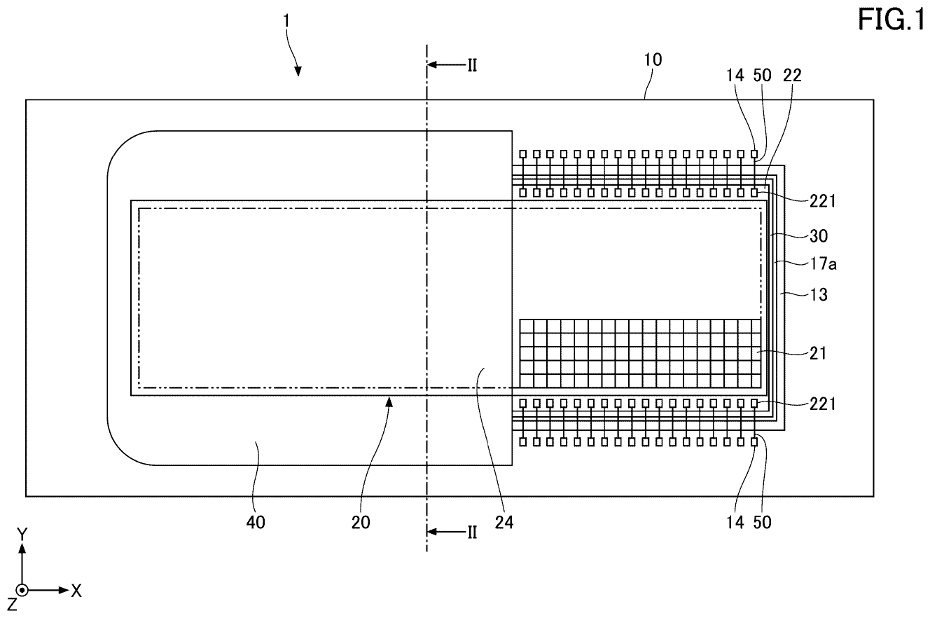

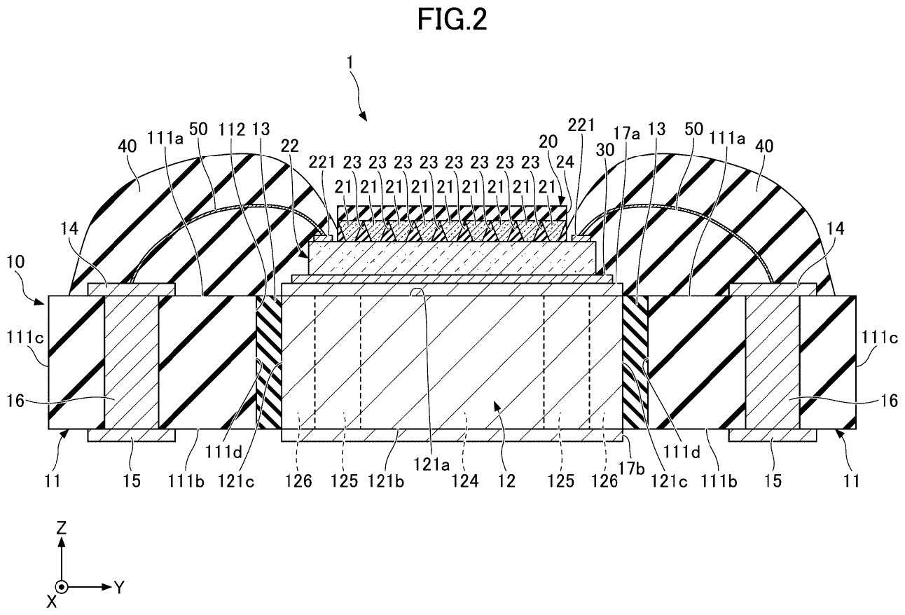

The overall configuration of a light emitting device 1 according to a first embodiment will be described with reference to FIG. 1 and FIG. 2. FIG. 1 is a schematic top view schematically illustrating an example of the light emitting device 1 according to the first embodiment. FIG. 2 is a schematic cross-sectional view of the light emitting device 1 taken through line II-II of FIG. 1.

As illustrated in FIG. 1 and FIG. 2, the light emitting device 1 includes a substrate 10 and a light source 20. In addition, the light emitting device 1 further includes a bonding member 30 and a covering member 40. The light emitting device 1 is mounted on a circuit board. The light emitting device 1 is connected to other electronic components and the like via the circuit board. In FIG. 1, for convenience of illustration, a portion of a wavelength conversion member 24 of the light source 20 and a portion of the covering member 40 are not depicted, so as to visualize a portion of the substrate 10 and a portion of the light source 20 covered by the wavelength conversion member 24 and the covering member 40.

### <Substrate 10>

The configuration of the substrate 10 will be described. The substrate 10 is a plate-shaped member having a substantially rectangular outer shape in a top view. However, the substrate 10 may have any other outer shape such as a substantially circular shape, a substantially elliptical shape, a substantially rectangular shape, or a substantially polygonal shape in a top view.

As illustrated in FIG. 2, the substrate 10 includes a first member 11 and a second member 12. In the first embodiment, the thickness (the dimension along the Z-axis direction) of the first member 11 and the thickness (the dimension along the Z-axis direction) of the second member 12 are substantially the same. However, the thickness of the first member 11 and the thickness of the second member 12 may be different from each other. The substrate 10 further includes an adhesive member 13, a first terminal 14, a second terminal 15, internal wiring 16, and metal films 17a and 17b.

The first member 11 is disposed outward relative to the second member 12 and the adhesive member 13. The first member 11 has a frame shape surrounding the second member 12 and the adhesive member 13 in a top view. However, the first member 11 is not limited to a member having a continuous shape such as a frame shape. For example, the first member 11 may be constituted by two or more plate-shaped members disposed so as to sandwich the second member 12 in a top view.

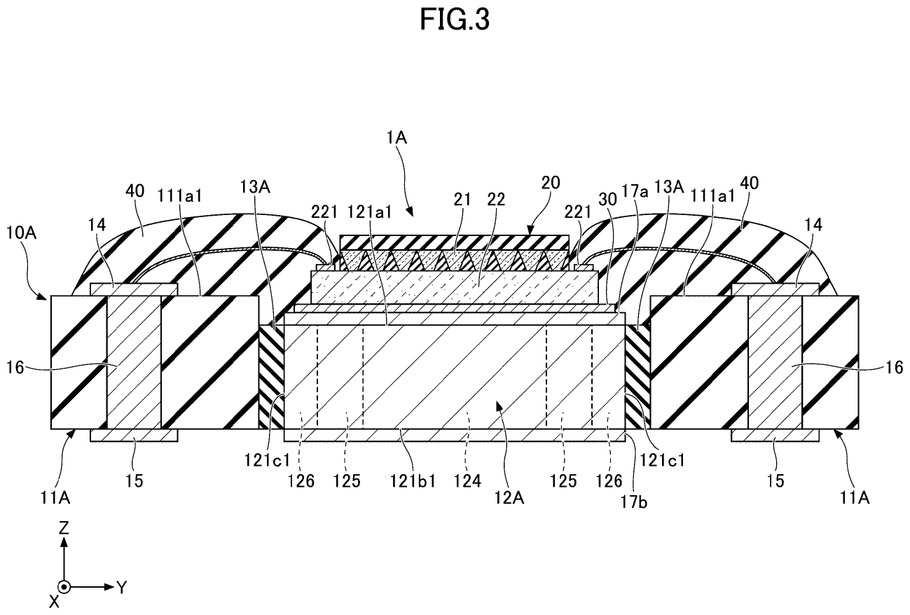

The first member 11 has an upper surface 111a, a lower surface 111b, one or more lateral surfaces 111a connecting the outer edge of the upper surface 111b and the outer edge of the lower surface 111c, and a through hole 112 extending from the upper surface 111a to the lower surface 111b. The through hole 112 is defined by a surface 111d connecting the inner edge of the upper surface 111a and the inner edge of the lower surface 111b. As illustrated in FIG. 2, the through hole 112 is provided at a position on the center side of the first member 11 in a cross-sectional view. The surface 111d surrounds the second member 12 in a top view. The surface 111d is hereinafter referred to as the “surface 111d defining the through hole 112.” The same applies to a modification of the first embodiment, a second embodiment, and modifications of the second embodiment, which will be described separately with reference to FIG. 3 to FIG. 7. In the first embodiment, the surface 111d defining the through hole 112 is along the Z-axis direction.

The first member 11 is preferably formed of a ceramic having good thermal conductivity such as aluminum nitride, aluminum oxide, silicon carbide, or silicon nitride, or a resin having good thermal conductivity, such as glass epoxy. However, the material constituting the first member 11 is not limited thereto.

The second member 12 is disposed inside the through hole 112. The second member 12 supports the light source 20. The second member 12 is a plate-shaped member having a substantially rectangular outer shape in a top view. However, the second member 12 may have any other shape such as a substantially circular shape, a substantially elliptical shape, or a substantially polygonal shape in a top view.

As illustrated in FIG. 2, the second member 12 has an upper surface 121a, a lower surface 121b, and lateral surfaces 121c connecting the outer edge of the upper surface 121a and the outer edge of the lower surface 121b. The lateral surfaces 121c are located on the periphery of the second member 12. Each of the lateral surfaces 121c of the second member 12 is hereinafter referred to as a “surface 121c located on the periphery of the second member 12.” The same applies to the modification of the first embodiment, the second embodiment, and the modifications of the second embodiment, which will be described separately with reference to FIG. 3 to FIG. 7.

The second member 12 includes a first region 124, second regions 125, and third regions 126. The first region 124 is the closest to the center of the second member 12 in a top view. Each of the second regions 125 is located outward of the first region 124 in a top view. One of the second regions 125 located on the +Y side and the other second region 125 located on the −Y side sandwich the first region 124. The third regions 126 are respectively located outward of the second regions 125. One of the third regions 126 located on the +Y side and the other third region 126 located on the −Y side sandwich the first region 124 and the second regions 125. The third regions 126 are located at end portions of the second member 12. In FIG. 2, the surface 121c located on the periphery of the second member 12 corresponds to a lateral surface connecting the outer edge of the upper surface (the surface on the +Z side) and the outer edge of the lower surface (the surface on the −Z side) of each of the third regions 126. In the first embodiment, the surface 121c located on the periphery of the second member 12 is along the Z-axis direction.

The first region 124 contains graphite. The first region 124 overlapping a number of light emitting elements 21 of the light source 20 in a top view contains graphite having good thermal conductivity. Thus, the heat dissipation of the second member 12 can be improved. As a result, the heat dissipation of the substrate 10 can be improved.

The volume fraction of graphite in the first region 124 is preferably 70 vol % or more and 100 vol % or less. If the volume fraction of graphite in the first region 124 is less than 70 vol %, the heat dissipation efficiency of the second member 12 is not possibly obtained. The “volume fraction” of a substance M in a region A is the percentage of the volume occupied by the substance M relative to the total volume of the region. For example, when the region A is the first region 124 and the substance M is graphite, the “volume fraction of graphite in the first region 124” corresponds to the percentage of the volume occupied by graphite in the first region 124 relative to the total volume of the first region 124.

The volume fraction of graphite in the first region 124 may be uniform regardless of the position in the first region 124. Alternatively, the volume fraction of graphite in the first region 124 may vary depending on the position in the first region 124. For example, the volume fraction of graphite in the first region 124 may vary continuously from the center of the first region 124 toward the outer side of the first region 124.

The first region 124 may contain any other material such as a thermally conductive material containing at least one of a metal or a ceramic. In a case where the first region 124 contains a thermally conductive material including at least one of a metal or a ceramic, the strength of the second member 12 can be improved. Examples of the metal in the thermally conductive material include copper, aluminum, nickel, titanium, platinum, gold, and silver. However, the metal in the thermally conductive material is not limited thereto. Examples of the ceramic in the thermally conductive material include aluminum nitride, aluminum oxide, silicon carbide, and silicon nitride. However, the ceramic in the thermally conductive material is not limited thereto. Among these thermally conductive materials containing at least one of metal or ceramic, copper and aluminum having good thermal conductivity and processability are preferable. The thermally conductive material containing at least one of a metal or a ceramic is hereinafter simply referred to as the “thermally conductive material.”

The volume fraction of the thermally conductive material in the first region 124 may be uniform regardless of the position in the first region 124. Alternatively, the volume fraction of the thermally conductive material in the first region 124 may vary depending on the position in the first region 124. For example, the volume fraction of the thermally conductive material in the first region 124 may vary continuously from the center of the first region 124 toward the outer side of the first region 124. In particular, from the viewpoint of improving the strength of the second member 12, the volume fraction of the thermally conductive material in the first region 124 preferably increases from the center toward the outer side of the first region 124.

From the viewpoint of improving the heat dissipation of the second member 12 and improving the strength of the second member 12, the volume fraction of graphite in the first region 124 may continuously decrease from the center toward the outer side of the first region 124, and the volume fraction of the thermally conductive material in the first region 124 may continuously increase from the center toward the outer side of the first region 124.

A second region 125 contains graphite and a thermally conductive material. The second region 125 may contain any other material different from graphite and the thermally conductive material. In addition to the first region 124, the second region 125 contains both graphite and the thermally conductive material, and thus the heat dissipation and the strength of the second member 12 can be improved.

The volume fraction of graphite in the second region 125 is lower than the volume fraction of graphite in the first region 124. In other words, the heat dissipation of the second member 12 can be further improved by increasing the volume fraction of graphite in the first region 124 overlapping a number of light emitting elements 21 of the light source 20 in a top view, as compared to the volume fraction of graphite in the second region 125 located outward of the first region 124.

The volume fraction of graphite in the second region 125 is preferably 30 vol % or more and 70 vol % or less. If the volume fraction of graphite in the second region 125 is less than 30 vol, desired heat dissipation efficiency of the second member 12 may not be able to be obtained. If the volume fraction of graphite in the second region 125 exceeds 70 vol %, the strength of the second member 12 is potentially decreased.

The volume fraction of graphite in the second region 125 may be uniform regardless of the position in the second region 125. Alternatively, the volume fraction of graphite in the second region 125 may vary depending on the position in the second region 125. For example, the volume fraction of graphite in the second region 125 may vary continuously from the inner side toward the outer side of the second region 125.

In a case where the first region 124 contains the thermally conductive material, the volume fraction of the thermally conductive material in the second region 125 is higher than the volume fraction of the thermally conductive material in the first region 124. The strength of the second member 12 can be further improved by increasing the volume fraction of the thermally conductive material in the second region 125, as compared to the volume fraction of the thermally conductive material in the first region 124 located inward of the second region 125 in a top view.

The volume fraction of the thermally conductive material in the second region 125 may be uniform regardless of the position in the second region 125. Alternatively, the volume fraction of the thermally conductive material in the second region 125 may vary depending on the position in the second region 125. For example, the volume fraction of the thermally conductive material in the second region 125 may vary continuously from the inner side toward the outer side of the second region 125. In particular, from the viewpoint of improving the strength of the second member 12, the volume fraction of the thermally conductive material in the second region 125 preferably increases from the inner side toward the outer side of the second region 125.

From the viewpoint of improving the heat dissipation of the second member 12 and improving the strength of the second member 12, the volume fraction of graphite in the second region 125 may continuously decrease from the inner side toward the outer side of the second region 125, and the volume fraction of the thermally conductive material in the second region 125 may continuously increase from the inner side toward the outer side of the second region 125.

A third region 126 contains a thermally conductive material. The volume fraction of the thermally conductive material in the third region 126 is higher than the volume fraction of the thermally conductive material in the second region 125. That is, the strength of the second member 12 can be further improved by increasing the volume fraction of the thermally conductive material in the third region 126 that is in contact with other members such as the adhesive member 13, as compared to the volume fraction of the thermally conductive material in the second region 125 located inward of the third region 126 in a top view. Further, by increasing the volume fraction of the thermally conductive material in the third region 126 as compared to the volume fraction of the thermally conductive material in the second region 125, each end portion of the second member 12 such as the surface 121c located on the periphery of the second member 12 can be easily processed.

The volume fraction of the thermally conductive material in the third region 126 may be uniform regardless of the position in the third region 126. Alternatively, the volume fraction of the thermally conductive material in the third region 126 may vary depending on the position in the third region 126. For example, the volume fraction of the thermally conductive material in the third region 126 may vary continuously from the inner side toward the outer side of the third region 126. In particular, from the viewpoint of improving the strength and the processability of the second member 12, the volume fraction of the thermally conductive material in the third region 126 preferably increases from the inner side toward the outer side of the third region 126. The third region 126 may be formed only of the thermally conductive material.

The third region 126 may contains any other material such as graphite. From the viewpoint of improving the strength and the processability of the second member 12, the volume fraction of graphite in the third region 126 is preferably lower than the volume fraction of graphite in the second region 125.

The volume fraction of graphite in the third region 126 may be uniform regardless of the position in the third region 126. Alternatively, the volume fraction of graphite in the third region 126 may vary depending on the position in the third region 126. For example, the volume fraction of graphite in the third region 126 may vary continuously from the inner side toward the outer side of the third region 126.

From the viewpoint of improving the heat dissipation of the second member 12 and improving the strength and the processability of the second member 12, the volume fraction of graphite in the third region 126 may continuously decrease from the inner side toward the outer side of the third region 126, and the volume fraction of the thermally conductive material in the third region 126 may continuously increase from the inner side toward the outer side of the third region 126.

In the second member 12, the volume fraction of graphite decreases in the order of the first region 124, the second region 125, and the third region 126. The volume fraction of graphite may continuously decrease from the center of the second member 12, where the first region 124 is located, toward each end portion of the second member 12 where the third region 126 is located.

In the second member 12, the volume fractions of the thermally conductive materials increase in the order of the first region 124, the second region 125, and the third region 126. The volume fractions of the thermally conductive materials may continuously increase from the center of the second member 12, where the first region 124 is located, toward each end portion of the second member 12 where the third region 126 is located. Each of the thermally conductive material in the first region 124, the thermally conductive material in the second region 125, and the thermally conductive material in the third region 126 preferably contains at least one of copper or aluminum. The first region 124, the second region 125, and the third region 126 may contain the same thermally conductive material or may contain different thermally conductive materials. If each end portion of the second member 12 is not processed, for example, the third region 126 is not necessarily provided.

If the width dimension (dimension along the Y-axis direction) of the second member 12 is set to 100%, the ratio of the width dimension (dimension along the Y-axis direction) of the first region 124 to the width dimension of the second member 12 is, for example, 40% or more and 80% or less. The ratio of the width dimension of a second region 125 located on the +Y side to the width dimension of the second member 12 is, for example, 5% or more and 15% or less, and the ratio of the width dimension of a second region 125 located on the −Y side to the width dimension of the second member 12 is, for example, 5% or more and 15% or less. The ratio of the width dimension of a third region 126 located on the +Y side to the width dimension of the second member 12 is, for example, 5% or more and 15% or less, and the ratio of the width dimension of a third region 126 located on the −Y side to the width dimension of the second member 12 is, for example, 5% or more and 15% or less. However, the ratio of the width dimension of the first region 124 to the width dimension of the second member 12, the ratios of the width dimensions of the second regions 125 to the width dimension of the second member 12, and the ratios of the width dimensions of the third regions 126 to the width dimension of the second member 12 are not limited thereto.

The adhesive member 13 is disposed between the first member 11 and the second member 12. The adhesive member 13 fixes the second member 12 to the inner side of the through hole 112 of the first member 11. As illustrated in FIG. 2, the outer edge of the adhesive member 13 is in contact with the surface 111d defining the through hole 112 of the first member 11. The inner edge of the adhesive member 13 is in contact with the surface 121c located on the periphery of the second member 12.

Examples of a material constituting the adhesive member 13 include: resin materials such as an epoxy resin, an acrylic resin, a urethane resin, and a silicone resin; conductive paste materials obtained by mixing metal powder into resin materials; and metal materials. However, the material constituting the adhesive member 13 is not limited thereto.

The first terminal 14 is provided on the upper surface 111a of the first member 11. The upper surface (the surface on the +Z side) of the first terminal 14 is connected to one end of a conductive wire 50. The other end of the conductive wire 50 is connected to a third terminal 221 disposed on the upper surface (the surface on the +Z side) of a wiring substrate 22 in the light source 20. That is, the first terminal 14 and the third terminal 221 are electrically connected to each other via the conductive wire 50.

The second terminal 15 is provided on the lower surface 111b of the first member 11. The lower surface (the surface on the −Z side) of the second terminal 15 is connected to, for example, wiring provided on the upper surface (the surface on the +Z side) of the circuit board. The wiring provided on the upper surface of the circuit board is electrically connected to an external power source. That is, the second terminal 15 is electrically connected to the external power source via the wiring provided on the upper surface of the circuit board.

The internal wiring 16 is provided in a via that extends between the upper surface 111a and the lower surface 111b of the first member 11. The via in which the internal wiring 16 is provided outward relative to the through hole 112. The upper end (the end on the +Z side) of the internal wiring 16 is bonded to the lower surface (the surface on the −Z side) of the first terminal 14. The lower end (the end on the −Z side) of the internal wiring 16 is bonded to the upper surface (the surface on the +Z side) of the second terminal 15. The first terminal 14 and the second terminal 15 are electrically connected to each other via the internal wiring 16. That is, the third terminal 221 on the wiring substrate 22 is electrically connected to the external power source via the first terminal 14, the second terminal 15, the internal wiring 16, and the wiring provided on the upper surface of the circuit substrate. When the light source 20 performs a light emitting operation, electric power from the external power source is supplied to the light source 20 through the first terminal 14, the second terminal 15, the internal wiring 16, and the third terminal 221.

Examples of a material constituting each of the first terminal 14, the second terminal 15, and the internal wiring 16 include gold, silver, copper, nickel, palladium, and aluminum. However, the material constituting each of the first terminal 14, the second terminal 15, and the internal wiring 16 is not limited thereto.

The metal film 17a is provided on the upper surface 121a of the second member 12. By bonding the upper surface 121a of the second member 12 and the lower surface (the surface on the −Z side) of the bonding member 30, facing the upper surface 121a of the second member 12, with the metal film 17a interposed therebetween, the adhesion between the second member 12 and the bonding member 30 can be improved. In particular, the second member 12 contains graphite, and thus it is preferable to bond the upper surface 121a of the second member 12 and the lower surface of the bonding member 30 to each other with the metal film 17a interposed therebetween.

The metal film 17b is provided on the lower surface 121b of the second member 12. By bonding the lower surface 121b of the second member 12 and the upper surface of the circuit board, facing the lower surface 121b of the second member 12, with the metal film 17b interposed therebetween, the adhesion between the second member 12 and the circuit board can be improved. In particular, the second member 12 contains graphite, and thus it is preferable to bond the lower surface 121b of the second member 12 and the upper surface of the circuit board to each other with the metal film 17b interposed therebetween.

Examples of a material constituting each of the metal films 17a and 17b include gold, silver, copper, nickel, palladium, and aluminum. However, the material constituting each of the metal films 17a and 17b is not limited thereto.

### <Light Source 20>

Next, the configuration of the light source 20 will be described. The light source 20 is disposed above the substrate 10. More specifically, the light source 20 is disposed above the second member 12 of the substrate 10 with the metal film 17a and the bonding member 30 interposed therebetween. The light source 20 emits white light. However, light emitted from the light source 20 is not limited to white light, and may be light having a specific wavelength, such as blue light. Further, the wavelength and the chromaticity of the light emitted from the light source 20 may be appropriately selected according to the use of the light emitting device 1.

As illustrated in FIG. 1, the light source 20 has a substantially rectangular outer shape in a top view. However, the light source 20 may have any other outer shape such as a substantially circular shape, a substantially elliptical shape, or a substantially polygonal shape in a top view. As illustrated in FIG. 2, the light source 20 includes a light emitting element 21 and the wiring substrate 22. The light source 20 further includes a light-shielding member 23 and the wavelength conversion member 24.

The light source 20 includes a plurality of light emitting elements 21 arranged in a matrix along the XY plane. Each of the plurality of light emitting elements 21 is a semiconductor light emitting element such as a light emitting diode (LED) or a laser diode (LD). Each of the light emitting elements 21 includes an n-type semiconductor layer, an active layer, and a p-type semiconductor layer that are sequentially layered in the Z-axis direction. The light emitting elements 21 emit, for example, blue light. The n-type semiconductor layer, the active layer, and the p-type semiconductor layer of each of the light emitting elements 21 are composed of, for example, nitride-based semiconductors such as InₓAl_{y}Ga_{1-x-y}N (0≤x, 0≤y, x+y≤1).

The lower surfaces (the surfaces on the −Z side) of the light emitting elements 21 are bonded to wiring provided on the upper surface (the surface on the +Z side) of the wiring substrate 22 via a pair of positive and negative electrodes, for example. The wiring provided on the upper surface of the wiring substrate 22 is electrically connected to the third terminal 221. Therefore, electric power from the external power source is supplied to the light emitting elements 21 through the first terminal 14, the second terminal 15, and the internal wiring 16 of the substrate 10, the third terminal 221 provided on the upper surface of the wiring substrate 22 and the wiring, and the pair of positive and negative electrodes.

The peak emission wavelength of the light emitting elements 21 is preferably 400 nm or more and 530 nm or less, more preferably 420 nm or more and 490 nm or less, and even more preferably 450 nm or more and 475 nm or less, from the viewpoint of emission efficiency, excitation of a wavelength conversion substance, and the like. However, the peak emission wavelength of the light emitting elements 21 is not limited thereto.

As illustrated in FIG. 2, the light-shielding member 23 is disposed between adjacent light emitting elements 21. Therefore, the light-shielding member 23 covers the lateral surfaces of the adjacent light emitting elements 21. The light-shielding member 23 is preferably composed of a resin material containing a light reflective substance in order to improve the light extraction efficiency of the light source 20. Examples of the light reflective substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide. Further, examples of the resin material include resin materials whose main components are thermosetting resins such as an epoxy resin, an epoxy-modified resin, a silicone resin, a silicone-modified resin, and a phenol resin.

The wavelength conversion member 24 is a member that covers the upper surfaces of the plurality of light emitting elements 21. The wavelength conversion member 24 has a substantially rectangular outer shape in a top view. However, the wavelength conversion member 24 may have any other outer shape such as a substantially circular shape, a substantially elliptical shape, or a substantially polygonal shape.

The upper surface (the surface on the +Z side) of the wavelength conversion member 24 corresponds to a light extraction surface of the light source 20. The wavelength conversion member 24 converts the wavelength of light emitted from the light emitting elements 21. The wavelength conversion member 24 contains a wavelength conversion substance and a base material including a light transmissive substance. As used herein, the “light transmissive” means that 60% or more of the light from the light emitting elements 21 is transmitted. Examples of the light transmissive substance include a resin material, a ceramic, and glass. Examples of the resin material include a silicone resin, a silicone-modified resin, an epoxy resin, an epoxy-modified resin, and a phenol resin. In particular, a silicone resin or a modified resin thereof having good light resistance and heat resistance is preferably used. However, the light transmissive substance is not limited thereto.

The wavelength conversion substance includes a cerium-activated yttrium aluminum garnet (YAG) phosphor. A portion of blue light emitted from the light emitting elements 21 is converted into yellow light by the YAG phosphor. Thus, white light is extracted from the light extraction surface of the light source 20. However, the wavelength conversion substance is not limited thereto. Other examples of the wavelength conversion substance include cerium-activated lutetium aluminum garnet (LAG), europium- and/or chromium-activated nitrogen-containing calcium aluminosilicate (CaO—Al₂O₃—SiO₂), europium-activated silicate ((Sr,Ba)₂SiO₄), α-SiAlON phosphors, β-SiAlON phosphors, and the like. The wavelength conversion substance may be dispersed in the base member or may be provided on the base member.

The wiring substrate 22 is a silicon substrate including an integrated circuit for controlling the light emitting operation of the plurality of light emitting elements 21. However, the wiring substrate 22 is not limited to the silicon substrate. The wiring substrate 22 may be a semiconductor substrate other than silicon, a ceramic substrate, a resin substrate, or the like.

Examples of the integrated circuit included in the wiring substrate 22 include an electronic circuit such as an application specific integrated circuit (ASIC). The integrated circuit is electrically connected to the wiring provided on the upper surface of the wiring substrate 22 and the third terminal 221.

### <Bonding Member 30>

As illustrated in FIG. 1 and FIG. 2, the bonding member 30 is disposed between the substrate 10 and the light source 20. More specifically, the upper surface (the surface on the +Z side) of the bonding member 30 is bonded to the lower surface of the wiring substrate 22. The lower surface (the surface on the −Z side) of the bonding member 30 is bonded to the upper surface (the surface on the +Z side) of the metal film 17a.

Examples of a material constituting the bonding member 30 include metals such as gold, silver, copper, tin, and aluminum, and alloys such as gold-tin. However, the material constituting the bonding member 30 is not limited thereto.

### <Covering Member 40>

As illustrated in FIG. 1 and FIG. 2, the covering member 40 is a light shielding member that is disposed outward relative to the outermost light emitting element 21 among the plurality of light emitting elements 21. Further, the covering member 40 covers the conductive wire 50 and the like. The covering member 40 has a frame shape surrounding the plurality of light emitting elements 21 in a top view. However, the covering member 40 may have a shape other than the frame shape in a top view.

Examples of the covering member 40 contain a resin containing a filler having a light shielding property. Examples of the resin include a silicone resin, a modified silicone resin, an epoxy resin, a modified epoxy resin, and an acrylic resin. Examples of the filler having a light shielding property include light absorbing materials such as pigments, carbon black, titanium black, and graphite; and light reflective substances such as titanium oxide, aluminum oxide, zinc oxide, barium carbonate, barium sulfate, boron nitride, aluminum nitride, and a glass filler. Examples of the external color of the covering member 40 include white having good light reflectivity, black having good light absorbency, and gray having light reflectivity and light absorbency. The outermost surface of the covering member 40 is preferably a light reflective white resin from the viewpoint of suppressing deterioration of the resin due to light absorption.

### First Modification of First Embodiment

Next, a light emitting device 1A according to a first modification of the first embodiment will be described with reference to FIG. 3. FIG. 3 is a schematic cross-sectional view of the light emitting device 1A according to the first modification of the first embodiment, taken along the YZ plane.

As illustrated in FIG. 3, the light emitting device 1A includes a substrate 10A and the light source 20. The light emitting device 1A further includes the bonding member 30 and the covering member 40. The light source 20, the bonding member 30, and the covering member 40 of the light emitting device 1A are the same as those of the first embodiment, and thus the description thereof will not be repeated.

The substrate 10A includes a first member 11A, a second member 12A, and an adhesive member 13A. Further, similar to the first embodiment, the substrate 10A further includes the first terminal 14, the second terminal 15, the internal wiring 16, and the metal films 17a and 17b.

In the substrate 10A, the thickness of the second member 12A is less than the thickness of the first member 11A. The light source 20 is disposed above the second member 12A. Thus, by making the thickness of the second member 12A low, the height position (the position on the +Z side) of the light extraction surface of the light source 20 can be lowered. Accordingly, the size of the light emitting device 1A can be reduced.

The height position of the upper surface 121a1 of the second member 12A is lower than the height position of an upper surface 111a1 of the first member 11A. Thus, the first terminal 14 provided on the upper surface 111a1 of the first member 11A and the third terminal 221 provided on the upper surface of the wiring substrate 22 can be closer to each other. As a result, the connection reliability of the conductive wire 50 connecting the first terminal 14 and the third terminal 221 can be improved. Other effects obtained by the light emitting device 1A are the same as or similar to those of the first embodiment.

### Second Embodiment

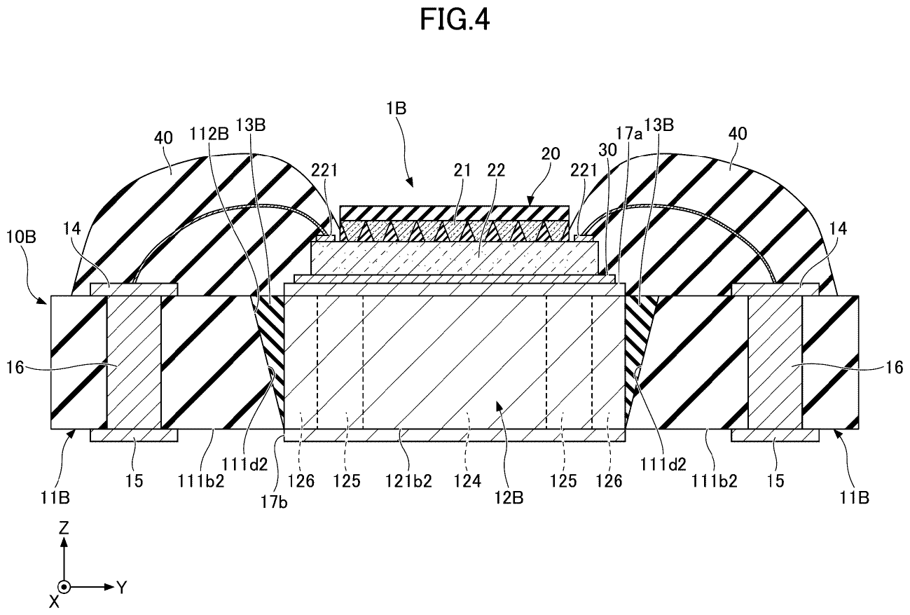

Next, a light emitting device 1B according to a second embodiment will be described with reference to FIG. 4. FIG. 4 is a schematic cross-sectional view of the light emitting device 1B according to the second embodiment, taken along the YZ plane.

The light emitting device 1B includes a substrate 10B and the light source 20. The light emitting device 1B further includes the bonding member 30 and the covering member 40. The light source 20, the bonding member 30, and the covering member 40 of the light emitting device 1B are the same as or similar to those of the first embodiment, and thus the description thereof will not be repeated.

The substrate 10B includes a first member 11B, a second member 12B, and an adhesive member 13B. Further, similar to the first embodiment, the substrate 10B further includes the first terminal 14, the second terminal 15, the internal wiring 16, and the metal films 17a and 17b.

As illustrated in FIG. 4, in the first member 11B, the shape of a surface 111d2 defining a through hole 112B is different from that of the first embodiment. More specifically, the one or more surfaces 111d2 defining the through hole 112B form a shape such that the width of the through hole 112B decreases toward a lower surface 111b2 of the first member 11B. Accordingly, a gap between the lower surface 111b2 of the first member 11B and a lower surface 121b2 of the second member 12B can be narrowed. As a result, leakage of the adhesive member 13B, disposed between the first member 11B and the second member 12B, from the gap between the lower surface 111b2 of the first member 11B and the lower surface 121b2 of the second member 12B can be suppressed. Other effects obtained by the light emitting device 1B are the same as or similar to those of the first embodiment.

A shape like the shape formed by the one or more surfaces 111d2 defining the through hole 112B, which allows the width of the through hole 112B to decrease toward the lower surface 111b2 of the first member 11B, is hereinafter referred to as a “tapered shape that tapers downward (toward the −Z side).” The same applies to the modifications of the second embodiment, which will be described separately with reference to FIG. 5 to FIG. 7.

The one or more surfaces 111d2 defining the through hole 112B may form a shape such that the width of the through hole 112B increases toward the lower surface 111b2 of the first member 11B. With this configuration, for example, if the adhesive member 13B contains a material having good thermal conductivity, such as a conductive paste material, the width of a heat transfer path can be increased toward the lower surface 111b2 of the first member 11B. Thus, the heat dissipation of the substrate 10B can be improved.

### First Modification of Second Embodiment

Next, a light emitting device 1C according to a first modification of the second embodiment will be described with reference to FIG. 5. FIG. 5 is a schematic cross-sectional view of the light emitting device 1C according to the first modification of the second embodiment, taken along the YZ plane.

The light emitting device 1C includes a substrate 10C and the light source 20. The light emitting device 1C further includes the bonding member 30 and the covering member 40. The light source 20, the bonding member 30, and the covering member 40 of the light emitting device 1C are the same as or similar to those of the first embodiment and the second embodiment, and thus the description thereof will not be repeated.

The substrate 10C includes a first member 11C, a second member 12C, and an adhesive member 13C. Further, similar to the first embodiment, the substrate 10C further includes the first terminal 14, the second terminal 15, the internal wiring 16, and the metal films 17a and 17b.

In the first member 11C, one or more surfaces 111d3 defining a through hole 112C form a tapered shape such that the through hole 112C is tapered downward. With this configuration, leakage of the adhesive member 13C, disposed between the first member 11C and the second member 12C, from a gap between a lower surface 111b3 of the first member 11C and a lower surface 121b3 of the second member 12C can be suppressed. Alternatively, the one or more surfaces 111d3 defining the through hole 112C may form a shape such that the width of the through hole 112C increases toward the lower surface 111b3 of the first member 11C.

The thickness of the second member 12C is less than the thickness of the first member 11C. Accordingly, the size of the light emitting device 1C can be reduced. Further, the height position of an upper surface 121a3 of the second member 12C is lower than the height position of an upper surface 111a3 of the first member 11C. Thus, the first terminal 14 provided on the upper surface 111a3 of the first member 11C and the third terminal 221 provided on the upper surface of the wiring substrate 22 can be brought closer to each other. As a result, the connection reliability of the conductive wire 50 connecting the first terminal 14 and the third terminal 221 can be improved. Other effects obtained by the light emitting device 1C are the same as or similar to those of the first embodiment and the second embodiment.

### Second Modification of Second Embodiment

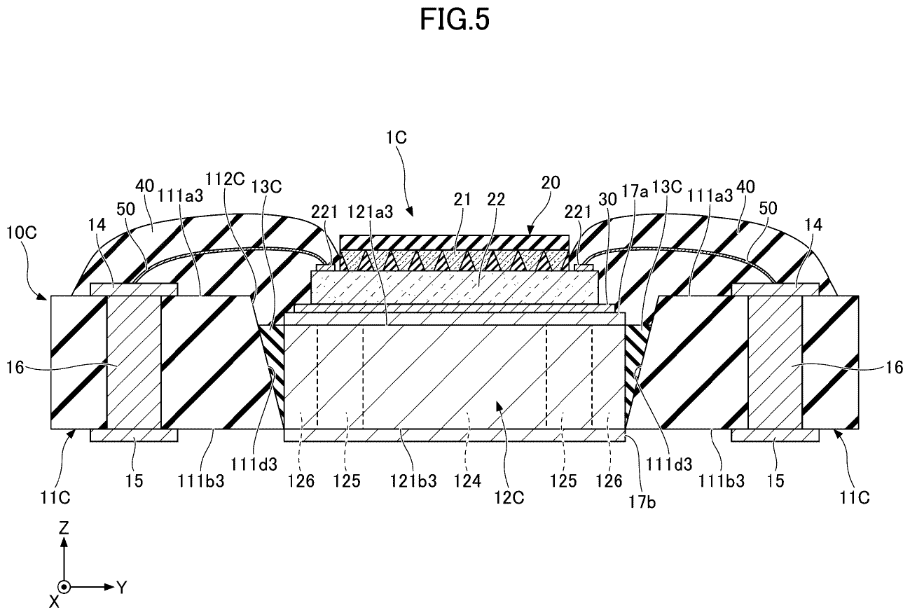

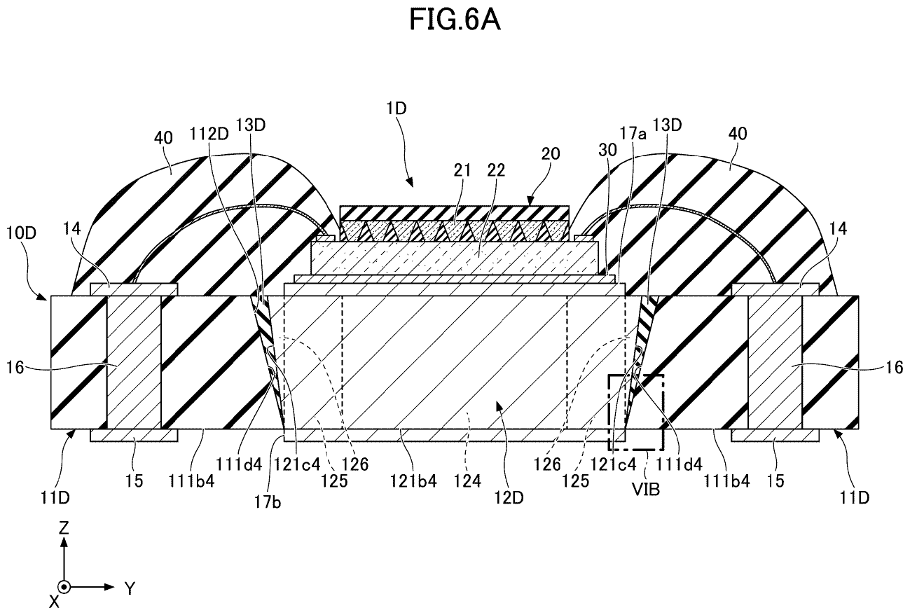

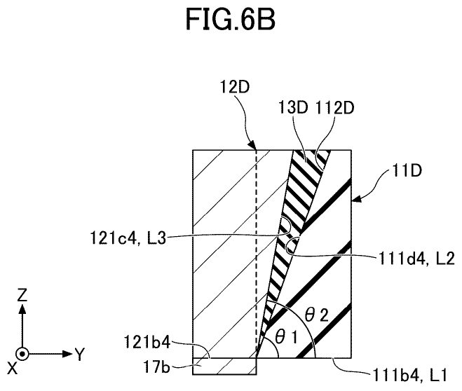

Next, a light emitting device 1D according to a second modification of the second embodiment will be described with reference to FIG. 6A and FIG. 6B. FIG. 6A is a schematic cross-sectional view of the light emitting device 1D according to the second modification of the second embodiment, taken along the YZ plane. FIG. 6B is a partially enlarged view of a region VIB illustrated in FIG. 6A.

The light emitting device 1D includes a substrate 10D and the light source 20. The light emitting device 1D further includes the bonding member 30 and the covering member 40. The light source 20, the bonding member 30, and the covering member 40 of the light emitting device 1D are the same as or similar to those of the first embodiment and the second embodiment, and thus the description thereof will not be repeated.

The substrate 10D includes a first member 11D, a second member 12D, and an adhesive member 13D. Further, similar to the first embodiment, the substrate 10D further includes the first terminal 14, the second terminal 15, the internal wiring 16, and the metal films 17a and 17b.

In the second member 12D, a surface 121c4 located on the periphery of the second member 12D has a shape such that the width of the second member 12D decreases toward a lower surface 121b4 of the second member 12D. That is, the one or more surfaces 121c4 located on the periphery of the second member 12D form a tapered shape such that the second member 12D tapers downward. Accordingly, downward movement (toward the −Z side) of the second member 12D is suppressed by the adhesive member 13D. As a result, detachment of the second member 12D from the first member 11D can be suppressed.

The surface 121c4 located on the periphery of the second member 12D may have a shape such that the width of the second member 12D increases toward the lower surface 121b4 of the second member 12D. Accordingly, the width of a heat transfer path can be increased toward the lower surface 121b4 of the second member 12D. Thus, the heat dissipation of the second member 12D can be improved.

Further, in the first member 11D, it is also preferable for one or more surfaces 111d4 defining a through hole 112D to form a tapered shape such that the through hole 112D is tapered downward. As illustrated in FIG. 6B, in a cross-sectional view, an angle θ1 formed by a lower surface 111b4 of the first member 11D and the surface 111d4 defining the through hole 112D is preferably less than an angle θ2 formed by the lower surface 111b4 of the first member 11D and the surfaces 121c4 located on the periphery of the second member 12D. The angle θ1 is an angle corresponding to an acute angle between a line L1 corresponding to the lower surface 111b4 of the first member 11D and a line L2 corresponding to the surface 111d4 defining the through hole 112D in a cross-sectional view. That is, the angle θ1 indicates the inclination or gradient of the taper of the through hole 112D. Further, the angle θ2 is an angle corresponding to an acute angle between the line L1 corresponding to the lower surface 111b4 of the first member 11D and a line L3 corresponding to the surface 121c4 located on the periphery of the second member 12D in a cross-sectional view. That is, the angle θ2 indicates the inclination or gradient of the taper of the second member 12D.

Because the angle θ1 is less than the angle θ2, a gap between the lower surface 111b4 of the first member 11D and the lower surface 121b4 of the second member 12D can be narrowed and also substantially the entire space between the first member 11D and the second member 12D can be filled with the adhesive member 13D. Accordingly, leakage of the adhesive member 13D from the gap between the lower surface 111b4 of the first member 11D and the lower surface 121b4 of the second member 12D can be suppressed. In addition, detachment of the second member 12D from the first member 11D can be suppressed.

However, the angle θ1 may be substantially the same as the angle θ2. In this case, no space is formed between the first member 11D and the second member 12D, and the second member 12D is fitted into the through-hole 112D. Thus, the surface 111d4 defining the through hole 112D of the first member 11D and the surface 121c4 located on the periphery of the second member 12D are in contact with each other. As a result, the first member 11D supports the second member 12D, and thus, even when the adhesive member 13D is not disposed between the first member 11D and the second member 12D, detachment of the second member 12D from the first member 11D can be suppressed. That is, while the configuration of the substrate 10D can be simplified, detachment of the second member 12D from the first member 11D can be suppressed.

The one or more surfaces 111d4 defining the through hole 112D may form a shape such that the width of the through hole 112D increases toward the lower surface 111b4 of the first member 11D.

For example, similar to the first embodiment, the one or more surfaces 111d4 defining the through hole 112D of the first member 11D may be formed along the Z-axis direction. Even in this case, downward movement of the second member 12D is suppressed by the adhesive member 13D. As a result, detachment of the second member 12D from the first member 11D can be suppressed. Other effects obtained by the light emitting device 1D are the same as or similar to those of the first embodiment and the second embodiment.

### Third Modification of Second Embodiment

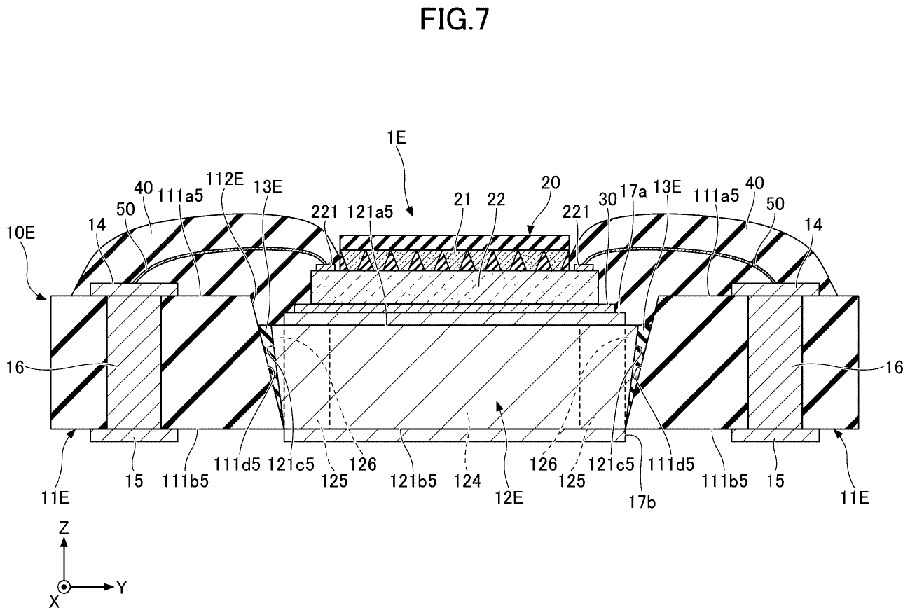

Next, a light emitting device 1E according to a third modification of the second embodiment will be described with reference to FIG. 7. FIG. 7 is a schematic cross-sectional view of the light emitting device 1E according to the third modification of the second embodiment, taken along the YZ plane.

The light emitting device 1E includes a substrate 10E and the light source 20. The light emitting device 1E further includes the bonding member 30 and the covering member 40. The light source 20, the bonding member 30, and the covering member 40 of the light emitting device 1E are the same as or similar to those of the first embodiment and the second embodiment, and thus the description thereof will not be repeated.

The substrate 10E includes a first member 11E, a second member 12E, and an adhesive member 13E. Further, the same as or similar to the first embodiment, the substrate 10E further includes the first terminal 14, the second terminal 15, the internal wiring 16, and the metal films 17a and 17b.

In the second member 12E, one or more surfaces 121c5 located on the periphery of the second member 12E form a tapered shape that is tapered downward. Accordingly, downward movement of the second member 12E is suppressed by the adhesive member 13E. As a result, detachment of the second member 12E from the first member 11E can be suppressed. Further, the surface 121c5 located on the periphery of the second member 12E may have a shape such that the width of the second member 12E increases toward a lower surface 121b5 of the second member 12E.

Further, in the first member 11E, one or more surfaces 111d5 defining a through hole 112E preferably has a tapered shape such that the through hole 112E is tapered downward. With this configuration, leakage of the adhesive member 13E, disposed between the first member 11E and the second member 12E, from a gap between a lower surface 111b5 of the first member 11E and the lower surface 121b5 of the second member 12E can be suppressed. Further, the one or more surfaces 111d5 defining the through hole 112E may form a shape such that the width of the through hole 112E increases toward the lower surface 111b5 of the first member 11E. However, the one or more surfaces 111d5 defining the through hole 112E of the first member 11E may be formed along the Z-axis direction.

The thickness of the second member 12E is less than the thickness of the first member 11E. Accordingly, the size of the light emitting device 1E can be reduced. Further, the height position of an upper surface 121a5 of the second member 12E is lower than the height position of an upper surface 111a5 of the first member 11E. Thus, the first terminal 14 provided on the upper surface 111a5 of the first member 11E and the third terminal 221 provided on the upper surface of the wiring substrate 22 can be brought closer to each other. As a result, the connection reliability of the conductive wire 50 connecting the first terminal 14 and the third terminal 221 can be improved. Other effects obtained by the light emitting device 1E are the same as or similar to those of the first embodiment and the second embodiment.

### Method of Manufacturing Light Emitting Device According to Embodiment

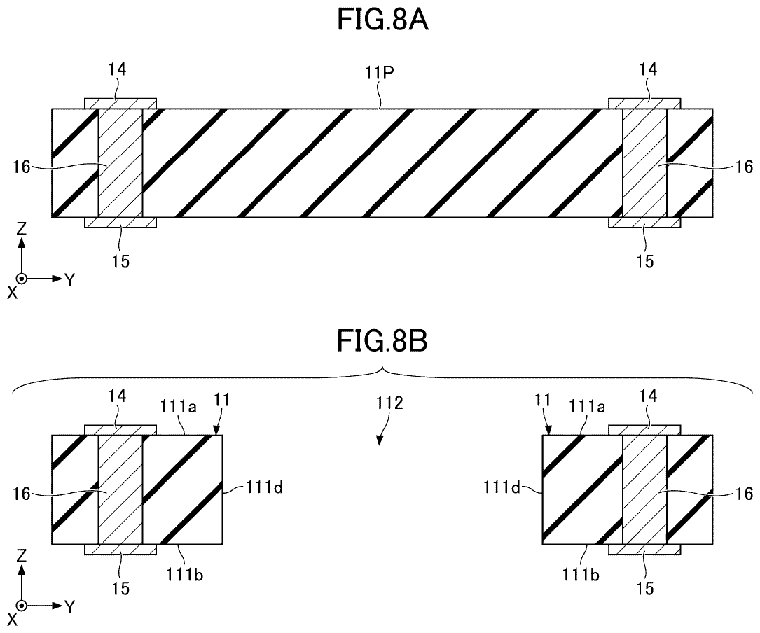

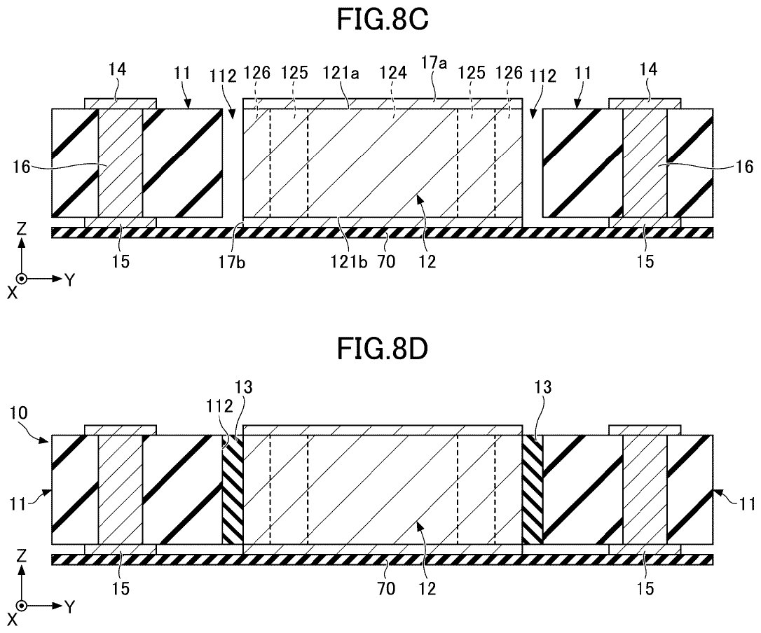

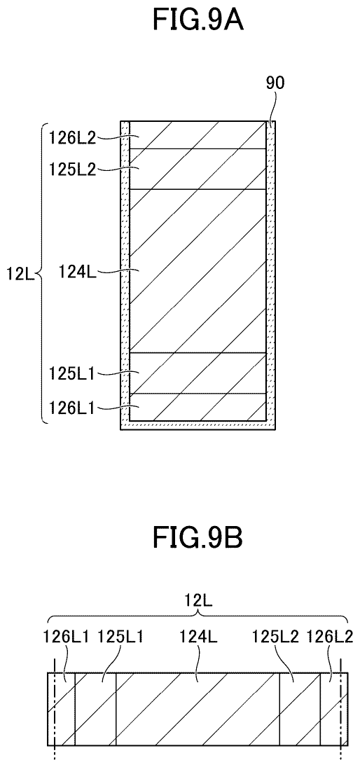

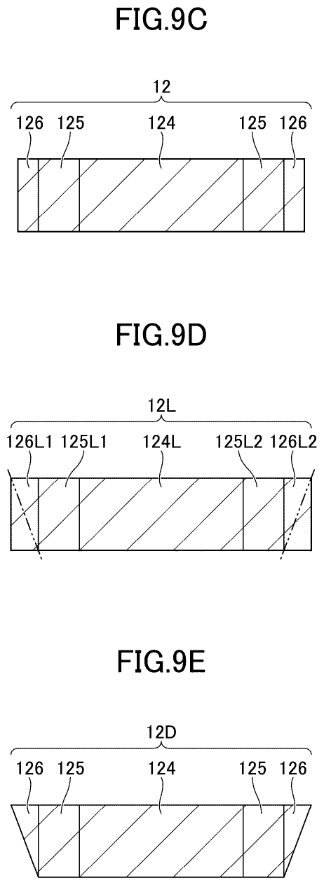

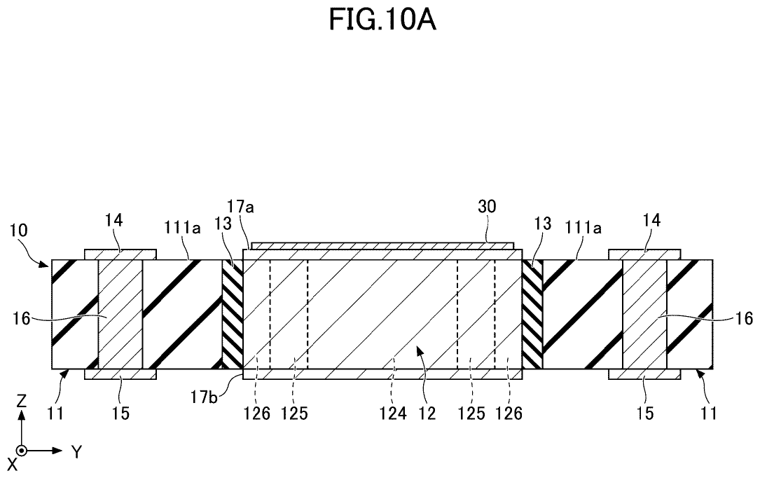

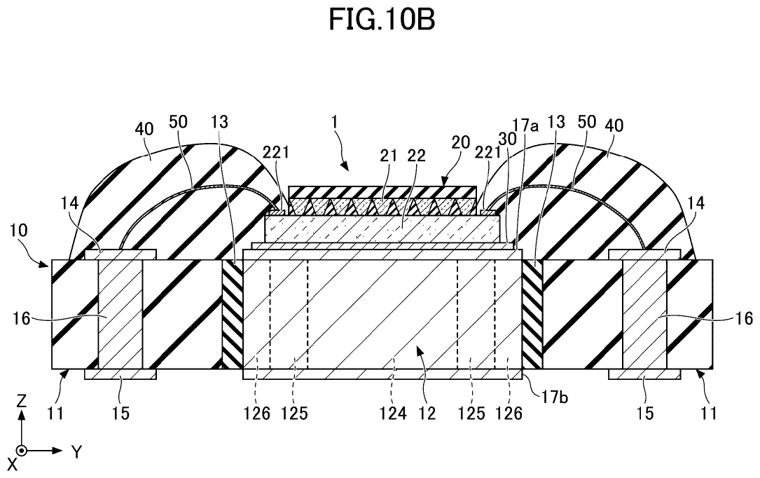

Next, a method of manufacturing a light emitting device according to an embodiment will be described. As an example, a method of manufacturing the light emitting device 1 according to the first embodiment will be described with reference to FIG. 8A to FIG. 10B. FIG. 8A to FIG. 8D are schematic cross-sectional views illustrating steps included in a method of manufacturing the substrate 10 of the light emitting device 1. FIG. 9A through 9D are schematic cross-sectional views illustrating a method of producing the second member 12. FIG. 10A and FIG. 10B are schematic cross-sectional views illustrating steps included in the method of manufacturing the light emitting device 1.

### <Method of Manufacturing Substrate 10>

First, the method of manufacturing the substrate 10 will be described as a premise for describing the method of manufacturing the light emitting device 1. As illustrated in FIG. 8A, a plate-shaped member 11P extending along the XY plane is prepared. The first terminal 14, the second terminal 15, and the internal wiring 16 may be provided on an upper surface 111a of the plate-shaped member 11P, a lower surface 111b of the plate-shaped member 11P, and inside the plate-shaped member 11P, respectively.

Subsequently, as illustrated in FIG. 8B, the through hole 112 extending from the upper surface 111a to the lower surface 111b of the plate-shaped member 11P is formed in a center region of the plate-shaped member 11P. By forming the through hole 112 in the plate-shaped member 11P, the first member 11 having a frame shape in a top view is obtained.

Examples of a method of forming the through hole 112 include a drilling method, a punching method, and a laser processing method. However, the method of forming the through hole 112 is not limited thereto. In the drilling method, if a cutting tool having an inclined blade such as a router bit is used, the one or more surfaces 111d defining the through hole 112 can be formed into a tapered shape that is tapered downward. In the punching method, if a mold in which the distance between two dies supporting the plate-shaped member 11P is made greater than the width of the punch is used, the one or more surfaces 111d defining the through hole 112 can be formed into a tapered shape that is tapered downward.

Subsequently, as illustrated in FIG. 8C, the second member 12 is disposed inside the through hole 112 of the first member 11. Before the second member 12 is disposed inside the through hole 112, a support tape 70 closing the lower side (the −Z side) of the through hole 112 is preferably attached. By attaching the support tape 70 in advance, the second member 12 can be fixed to a desired position.

The method of producing the second member 12 is, for example, as follows. An example of the method of producing the second member 12 will be described with reference to FIG. 9A to FIG. 9E. First, as illustrated in FIG. 9A, a first layer 126L1 corresponding to a third region 126 of the second member 12, a second layer 125L1 corresponding to a second region 125, a third layer 124L corresponding to a first region 124, a fourth layer 125L2 corresponding to a second region 125, and a fifth layer 126L2 corresponding to a third region 126 are stacked in the heat-resistant container 90 in this order from the bottom of the heat-resistant container 90. At this time, each time a layer is stacked in the heat-resistant container 90, the stacked layer may be pressurized.

The second layer 125L1, the third layer 124L, and the fourth layer 125L2 contain, for example, flake graphite having a particle diameter of 10 μm or more and 700 μm or less or substantially spherical graphite having a particle diameter of 8 μm or more and 40 μm or less. If the first layer 126L1 and the fifth layer 126L2 contain graphite, the first layer 126L1 and the fifth layer 126L2 may contain flake graphite having a particle diameter of 10 μm or more and 700 μm or less or substantially spherical graphite having a particle diameter of 8 μm or more and 40 μm or less.

The first layer 126L1 and the fifth layer 126L2 contain, for example, a thermally conductive material in the form of powder, such as a substantially spherical metal powder or ceramic powder, having a particle diameter of 1.4 μm or more and 20 μm or less. Similarly, the second layer 125L1 and the fourth layer 125L2 may contain a thermally conductive material in the form of powder, such as a substantially spherical metal powder or ceramic powder, having a particle diameter of 1.4 μm or more and 20 μm or less.

After a stack 12L is obtained by stacking the first layer to the fifth layer in the heat-resistant container 90, the heat-resistant container 90 is accommodated in a sintering device and the stack 12L is sintered. At this time, the stack 12L is preferably sintered while being pressurized in the stacking direction in which the layers of the stack 12L are stacked. For example, electric current sintering is performed while heating and pressurizing the stack 12L at a temperature of 500° C. or more and 900° C. or less and at a pressure of 10 Mpa or more and 90 Mpa or less. However, the method of sintering the stack 12L is not limited thereto.

After the stack 12L is sintered, the stack 12L is taken out from the heat-resistant container 90. Subsequently, the stack 12L is cut along the stacking direction so as to be divided into a plurality of small pieces by using a cutting device such as a wire saw or a disk saw. Finally, as illustrated in FIG. 9B, both end portions of each of the plurality of small pieces (end portions of the first layer 126L1 and the fifth layer 126L2) are cut and smoothed. In this manner, the second member 12 is obtained as illustrated in FIG. 9C. As illustrated in FIG. 9D, if both end portions of a small piece are obliquely cut at the time of cutting, the one or more surfaces 121c located on the periphery of the second member 12 can be formed into a tapered shape that is tapered downward as illustrated in FIG. 9E. In this manner, the second member 12D according to the second modification of the second embodiment can be obtained. The surface roughness of the cut surfaces of the obtained second member 12 varies according to a material constituting the second member 12, the volume fraction of the material, sintering conditions, and the like, but is preferably approximately 1.0 μm to 15.0 μm in terms of the arithmetic average roughness (Sz). The surface roughness of the second member 12 can be adjusted as appropriate according to the adhesive member 13. The surface roughness of the second member 12 may be adjusted by adjusting the material of the second member 12, the volume fraction of the material, sintering conditions, or the like, or by adjusting processing conditions for cutting the stack 12L.

As illustrated in FIG. 8C, the metal film 17a is formed on the upper surface 121a of the obtained second member 12. The metal film 17b is formed on the lower surface 121b of the second member 12. Examples of a method of forming the metal films 17a and 17b include wet processes such as a plating method, an inkjet method, a spin coating method, and a dipping method, and dry processes such as a vacuum deposition method and a sputtering method. Subsequently, the second member 12 is placed on the upper surface (the surface on the +Z side) of the support tape 70. The metal films 17a and 17b may be formed after the second member 12 is fixed to the first member 11.

Subsequently, as illustrated in FIG. 8D, for example, an adhesive resin paste is supplied to a space between the first member 11 and the second member 12. Examples of a method of supplying the adhesive resin paste include a dispensing method, a screen printing method, and the inkjet method. After the space is supplied, the adhesive resin paste is cured. In this manner, the adhesive member 13 is formed between the first member 11 and the second member 12. The adhesive member 13 may be formed by plating of a metal material. The adhesive member 13 fixes the second member 12 to the inner side of the through hole 112 of the first member 11. Subsequently, the support tape 70 is removed from the first member 11 and the second member 12. The substrate 10 is manufactured through the above steps.

### <Method of Manufacturing Light Emitting Device 1>

Next, the method of manufacturing the light emitting device 1 will be described. As illustrated in FIG. 10A, the bonding member 30 containing, for example, silver is formed on the upper surface of the metal film 17a. Examples of a method of forming the bonding member 30 include processes such as the screen printing method, the dispensing method, the ink jet method, the vacuum deposition method, and the sputtering method.

Subsequently, as illustrated in FIG. 10B, the light source 20, including the light emitting elements 21 and the wiring substrate 22, is disposed on the bonding member 30. Then, the light source 20 is fixed onto the bonding member 30 by being subjected to heat treatment in a reflow furnace or the like. Further, the conductive wire 50 is provided by, for example, wire bonding so as to connect the first terminal 14 provided on the upper surface 111a of the first member 11 and the third terminal 221 of the wiring substrate 22. Further, the covering member 40 is formed so as to cover the conductive wire 50. The covering member 40 is obtained by supplying, for example, an uncured white resin to a region overlapping the conductive wire 50 in a top view and then curing the white resin. The light emitting device 1 is manufactured through the above steps. The obtained light emitting device 1 is mounted on a circuit board or the like and is used.

The same or similar manufacturing method can be applied to the first modification of the first embodiment, the second embodiment, and the modifications of the second embodiment.

According to one embodiment of the present disclosure, a substrate and a light emitting device having good heat dissipation can be provided.

Although embodiments have been described in detail above, the above-described embodiments are non-limiting examples, and various modifications and substitutions can be made to the above-described embodiments without departing from the scope described in the claims.

What is claimed is:

1. A substrate comprising:
a first member having a through hole extending from an upper surface to a lower surface thereof; and
a second member disposed inside the through hole, wherein:
the second member includes:
a first region containing graphite,
a second region located outward of the first region in a top view, containing graphite and a thermally conductive material that contains at least one of a metal or a ceramic, and having a volume fraction of the graphite lower than a volume fraction of the graphite in the first region, and
a third region located outward of the second region in the top view, containing a thermally conductive material that contains at least one of a metal or a ceramic, and having a volume fraction of the thermally conductive material higher than a volume fraction of the thermally conductive material in the second region.

2. The substrate according to claim 1, wherein the first region further contains a thermally conductive material that contains at least one of a metal or a ceramic.

3. The substrate according to claim 1, wherein:
the volume fraction of the graphite in the first region is 70 vol % or more and 100 vol % or less, and
the volume fraction of the graphite in the second region is 30 vol % or more and 70 vol % or less.

4. The substrate according to claim 2, wherein each of the thermally conductive material of the first region, the thermally conductive material of the second region, and the thermally conductive material of the third region contains at least one of copper or aluminum.

5. The substrate according to claim 1, further comprising:
an adhesive member disposed between the first member and the second member, and configured to fix the second member to an inner side of the through hole, wherein:
one or more surfaces defining the through hole of the first member form a shape such that a width of the through hole decreases toward the lower surface of the first member.

6. The substrate according to claim 1, further comprising:
an adhesive member disposed between the first member and the second member, and configured to fix the second member to an inner side of the through hole, wherein:
one or more surfaces located at a periphery of the second member form a shape such that a width of the second member decreases toward a lower surface of the second member.

7. The substrate according to claim 1, further comprising:
an adhesive member disposed between the first member and the second member, and configured to fix the second member to an inner side of the through hole, wherein:
one or more surfaces defining the through hole of the first member form a shape such that a width of the through hole decreases toward the lower surface of the first member,
one or more surfaces located at a periphery of the second member form a shape such that a width of the second member decreases toward a lower surface of the second member, and
an angle formed by the lower surface of the first member and one of the one or more surfaces defining the through hole of the first member is less than an angle formed by the lower surface of the first member and one of the one or more surfaces located on the periphery of the second member in a cross-sectional view.

8. The substrate according to claim 1, wherein:
a thickness of the second member is less than a thickness of the first member, and
a position of an upper surface of the second member is lower than a position of an upper surface of the first member.

9. The substrate according to claim 1, wherein a metal film is disposed on each of an upper surface and a lower surface of the second member.

10. A light emitting device comprising:
a substrate; and
a light source disposed above the substrate, wherein:
the substrate comprises:
a first member having a through hole extending from an upper surface to a lower surface thereof, and
a second member disposed inside the through hole, and
the second member includes:
a first region containing graphite, and located at a position overlapping the light source in a top view,
a second region located outward of the first region in the top view, containing graphite and a thermally conductive material that contains at least one of a metal or a ceramic, and having a volume fraction of the graphite lower than a volume fraction of the graphite in the first region, and
a third region located outward of the second region in the top view, containing a thermally conductive material that contains at least one of a metal or a ceramic, and having a volume fraction of the thermally conductive material higher than a volume fraction of the thermally conductive material in the second region.
